(19) United States
(12) Patent Application Publication
(10) Pub. No.: US 2022/0178999 A1
(43) Pub. Date: Jun. 9, 2022

(54) SOLID-STATE POWER SWITCH PROGNOSTICS

(71) Applicant: ABB Schweiz AG, Baden (CH)

(72) Inventors: Rostan Rodrigues, Cary, NC (US); David Coats, Apex, NC (US)

(21) Appl. No.: 17/113,578

(22) Filed: Dec. 7, 2020

(51) Int. Cl. G01R 31/327; G01R 31/28

(52) U.S. Cl. CPC G01R 31/3274; G05B 23/0256; G01R 31/2829

(57) ABSTRACT

Systems, methods, techniques and apparatuses of prognostic testing are disclosed. One exemplary embodiment is a power switch system comprising a power switch; a current sensor; a test current injection circuit comprising: a first direct current (DC) bus rail including an output terminal and a first power supply terminal, a second DC bus rail including an input terminal and a second power supply terminal, a diode coupled to the first DC bus rail, and a leg coupled to the first DC bus rail between the diode and the first power supply terminal and coupled to the second DC bus rail between the input terminal and the second power supply terminal, the leg including a capacitor and a semiconductor device coupled in series; and a controller configured to operate the test current injection circuit to transmit a test current to the current sensor and receive a voltage based on the test current.

### BACKGROUND

The present disclosure relates generally to prognostic testing for solid-state power switches. Power switches undergo electrical, thermal, and mechanical stresses during their lifetime. These stresses cause a degradation of the power switch. After significant degradation, the power switch is no longer reliable in its operation and can fail to protect other components in a power system. Existing health monitoring for power system switches suffer from a number of shortcomings and disadvantages. For example, conventional health monitoring for mechanical switching in power applications such as breakers, relays, and contactors is not applicable to solid-state power switches. Furthermore, prognostic testing for power converter switches does not monitor failure modes specific to other solid-state switch applications. In view of these and other shortcomings in the art, there is a significant need for the unique apparatuses, methods, systems and techniques disclosed herein.

### DISCLOSURE OF ILLUSTRATIVE EMBODIMENTS

For the purposes of clearly, concisely and exactly describing non-limiting exemplary embodiments of the disclosure, the manner and process of making and using the same, and to enable the practice, making and use of the same, reference will now be made to certain exemplary embodiments, including those illustrated in the figures, and specific language will be used to describe the same. It shall nevertheless be understood that no limitation of the scope of the present disclosure is thereby created, and that the present disclosure includes and protects such alterations, modifications, and further applications of the exemplary embodiments as would occur to one skilled in the art with the benefit of the present disclosure.

### SUMMARY OF TIE DISCLOSURE

Exemplary embodiments of the disclosure include unique systems, methods, techniques and apparatuses for power switch prognostics. Further embodiments, forms, objects, features, advantages, aspects and benefits of the disclosure shall become apparent from the following description and drawings.

### BRIEF DESCRIPTION OF THE DRAWINGS

FIG. 1 illustrates an exemplary power switch system.

FIG. 2 is a flowchart illustrating an exemplary process for health monitoring.

FIGS. 3-8 are graphs illustrating electrical characteristics of the power switch system in FIG. 1 during prognostic testing.

FIGS. 9-10 illustrates additional exemplary power switch systems.

### DETAILED DESCRIPTION OF ILLUSTRATIVE EMBODIMENTS

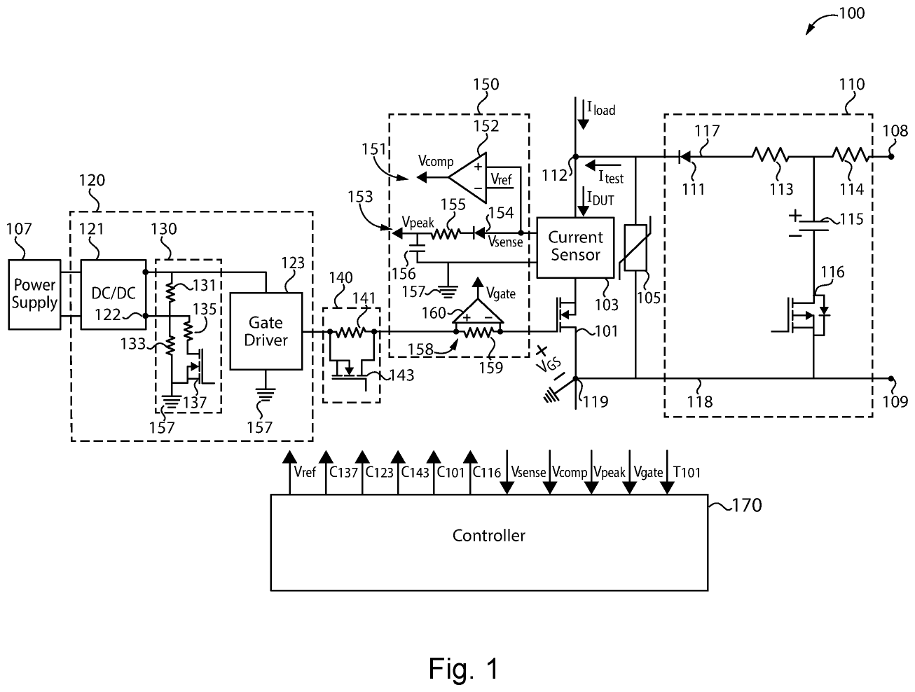

With reference to FIG. 1, there is illustrated an exemplary power switch system 100 configured to perform prognostic testing for power switch 101. It shall be appreciated that system 100 may be implemented in a variety of applications, including solid-state circuit breakers, solid-state relays, solid-state contactors, solid-state residual current devices, solid-state power controllers, solid-state static transfer switches, solid-state bypass switches, or other power switches structured to remain closed while the power system is in normal operation. In certain embodiments, power switch 101 is structured to conduct alternating current (AC) or direct current (DC).

System 100 includes power switch 101, which is the device under test. In the illustrated embodiment, power switch 101 is a metal-oxide-semiconductor field-effect transistor (MOSFET). In other embodiments, power switch 101 may include an insulated gate bipolar transistor (IGBT), a bipolar junction transistor (BJT), a silicon carbide (SiC) junction field-effect transistor switching device, another type of SiC-based switching device, a gallium nitride (GaN) switching device, or any other type of solid-state switch structured to selectively conduct electric current.

Power switch 101 is coupled in series with a current sensor 103 structured to conduct a current I_{DUT}, which includes a combination of load current I_{load} and test current Iₜₑₛₜ, measure the conducted current I_{DUT}, and transmit an output voltage Vₛₑₙₛₑ corresponding to electrical characteristics of the conducted current I_{DUT}. In certain embodiments, current sensor 103 may include a current transformer, a current sense resistor, a Rogowski coil current sensor, or a hall-effect sensor, to name but a few examples. It shall be appreciated that system 100 is applicable to series connection, parallel connection, or a combination of series-parallel connection of power switch 100 and other power switches.

A metal-oxide varistor (MOV) 105 is coupled in parallel with the series-coupled power switch 101 and current sensor 103. It is important to note that in order to differentiate between current Iₜₑₛₜ and MOV transient or leakage currents, current sensor 103 is placed in series with power switch 101 and MOV 105 is coupled in parallel to the series combination. As explained in more detail below, prognostic testing may be delayed for a short time until the MOV current transient terminates. This delay may be estimated by turnoff current value, system impedance, and MOV 105 rating. In certain embodiments, system 100 includes a separate current sensor structured to measure MOV 105 current transients.

System 100 includes a test current injection circuit 110 structured to transmit test current Iₜₑₛₜ to current sensor 103. Circuit 110 includes a first DC bus rail 117 coupled between output terminal 112 and power supply terminal 108; a second DC bus rail 118 coupled between input terminal 119 and power supply terminal 109; and a leg coupled between DC bus rail 117 and DC bus rail 118. Circuit 110 also includes diode 111, resistor 113, resistor 114, capacitor 115, and semiconductor device 116.

Diode 111 is coupled to DC bus rail 117 between output terminal 112 and resistor 113. Diode 111 is structured to block current conducting in the direction of the leg of circuit 110 from output terminal, but conduct test current Iₜₑₛₜ output from circuit 110 to current sensor 103 and power switch 101.

Resistor 113 is coupled to DC bus rail 117 between diode 111 and the leg of circuit 110. Resistor 113 is sized to limit a magnitude of test current Iₜₑₛₜ. Resistor 114 is coupled to DC bus rail 117 between the leg of circuit 110 and power supply terminal 108. Resistor 114 is structured to limit a magnitude of charging current flowing from a power supply coupled to terminals 108 and 109 to capacitor 115.

Terminals 108 and 109 are structured to receive a low voltage from a power supply. For example, terminals 108 and 109 may receive a voltage of less than 30V, to name but one example. In certain embodiments, terminals 108 and 109 receive the low voltage from power supply 107.

Capacitor 115 and semiconductor device 116 form the leg of circuit 110. Capacitor 115 is structured to store energy used for outputting test currents from circuit 110. Semiconductor device 116 includes a semiconductor switch and a diode arranged in an anti-parallel configuration. For example, semiconductor device 116 may include a p-channel MOSFET having an intrinsic body diode. In certain embodiments, capacitor 115 may include a plurality of capacitors. The semiconductor switch of semiconductor device 116 may be any type of semiconductor switch.

The diode of semiconductor device 116 is arranged such that capacitor 115 may be charged by a current conducted in a current path including terminal 108, resistor 114, capacitor 115, the diode of semiconductor device 116, and terminal 109. When the semiconductor switch is turned on, test current Iₜₑₛₜ is conducted in a current path including capacitor 115, resistor 113, diode 111, output terminal 112, current sensor 103, power switch 101, and input terminal 119.

System 100 includes a plurality of measuring circuits 150 including a threshold measurement circuit 151, a peak measurement circuit 153, and a gate leakage measurement circuit 158. The plurality of measuring circuits 150 are structured to measure electrical characteristics of system 100 and output voltages to a controller 170 which correspond to the measured electrical characteristics of system 100.

Threshold measurement circuit 151 includes a comparator 152 structured to receive output voltage Vₛₑₙₛₑ and a reference voltage V_{ref} from controller 170, compare output voltage Vₛₑₙₛₑ and reference voltage V_{ref}, and transmits an output voltage V_{comp} to controller 170, output voltage V_{comp} becoming a high output once the output voltage exceeds the reference voltage. For certain tests, the reference voltage corresponds to a gate threshold voltage, such as an initial gate threshold voltage of power switch 101. For other tests, reference voltage V_{ref} corresponds to a short-circuit threshold.

A peak measurement circuit 153 is structured to receive the output voltage Vₛₑₙₛₑ and output a peak voltage Vₚₑₐₖ corresponding to a peak current magnitude of the test current Iₜₑₛₜ. Peak measurement circuit 153 includes a current limiting resistor 155 coupled in series with a diode 154, and a capacitor 156 coupled between resistor 155 and a ground 157.

Gate leakage measurement circuit 158 includes a differential amplifier 160 coupled in parallel with gate resistor 159. Circuit 158 is structured to receive a voltage across gate resistor 159, amplify the received voltage, and output the amplified voltage V_{gate}. In another embodiment, gate leakage measurement circuit 158 includes an operational amplifier coupled between the gate and source of power switch 101, and structured to output voltage V_{gate}.

System 100 includes a controlled resistance circuit 140 including a resistor 141 and a semiconductor switch 143. Resistor 141 is sized so as to prolong the period of time between a gate voltage beginning to be applied to the gate of power switch 101 and the gate voltage exceeding the gate voltage threshold of power switch 101. Semiconductor switch 143 may be any type of semiconductor switch.

System 100 includes a controlled voltage circuit 120 structured to output either a standard gate voltage to power switch 101 or a reduced test gate voltage to power switch 101 based on a state of semiconductor switch 137. Circuit 120 includes a DC/DC converter 121 structured to receive DC from power supply 107 and output one of the two output voltages based on a feedback signal received at feedback terminal 122. Circuit 120 includes a prognostic circuit 130 including a resistor coupled across the output terminals of DC/DC converter 121, a resistor 133 coupled between resistor 131 and ground 157, and a resistor 135 and semiconductor switch 137 coupled together in series between resistor 131 and ground 157 such that resistor 133 is coupled in parallel with resistor 135 and semiconductor switch 137. When semiconductor switch 137 is opened, the feedback received at DC/DC converter terminal 122 will cause DC/DC converter 121 to output a standard output voltage to gate driver 123. When semiconductor switch 137 is closed, the feedback received at DC/DC converter terminal 122 will cause DC/DC converter 121 to output a reduced test voltage to gate driver 123. Gate driver 123 receives one of the two voltages from DC/DC converter 121 and outputs either the test gate voltage or the standard gate voltage to the gate of power switch 101.

System 100 includes a controller 170 configured to determine a health status, also known as a degradation, for the power switch based on degradation values for one or more of a gate leakage current of power switch 101, an on-resistance of power switch 101, a gate threshold voltage of power switch 101, and a drain current saturation of power switch 101. Controller 170 is structured to receive voltage Vₛₑₙₛₑ from current sensor 103, voltage V_{comp} from threshold measurement circuit 151, voltage Vₚₑₐₖ from peak measurement circuit 153, voltage V_{gate} from gate leakage measurement circuit 158, and a temperature T₁₀₁ from a temperature sensor. Controller 170 is also structured to output reference voltage V_{ref} to comparator 152 and to operate the switches of system 100 by outputting control signal C₁₃₇ to semiconductor switch 137, control signal C₁₂₃ to gate driver 123, control signal C₁₄₃ to semiconductor switch 143, and control signal C₁₁₆ to semiconductor device 116.

Controller 170 performs a prognostic test for each parameter used in determining a health status of power switch 101. Each prognostic test occurs over a short time. For example, each prognostic test may take less than 100 us. Each prognostic test may be carried out at predefined time intervals determined by the specific application of power switch 101. For example, each prognostic test may be carried out once per hour or once per day, to give but a few examples. The results of each test, including at least one of voltage Vₛₑₙₛₑ, V_{comp}, Vₚₑₐₖ, and V_{gate}, are received from the plurality of measuring circuits 150. The results may be stored in memory of controller 170 or may be stored remotely, such as on a remote server, depending on the activity available. Determining a degradation value for the power switch may include comparing the received voltages to historic results of the prognostic test, such as the initial results for each test or the test results at the time power switch 101 was installed for operation in the power switch system 100.

The first prognostic test controller 170 may perform is the gate leakage current test. While power switch 101 is on, a gate leakage current conducted through a gate to source channel of power switch 101 is measured using differential amplifier 160. For a healthy power switch in the on-state under steady-state conditions, the gate leakage current should be negligible, but due to degradation, the gate leakage current will increase. This gate leakage current creates the voltage across gate resistor 159, which is measured by differential amplifier 160. The magnitude of voltage V_{gate} corresponds to the magnitude of the gate leakage current.

For the remaining parameters used to determine the health status of power switch 101, controller 170 the prognostic tests generally include determining power switch 101 is in a zero current condition, applying a gate voltage to power switch 101, transmitting the test current to current sensor 103, receiving at least one voltage output from the plurality of measuring circuits 150, storing the received voltage output in memory, and determining a degradation value for the tested parameter.

The second prognostic test controller 170 may perform is the on-resistance test. While applying a standard gate voltage to power switch 101 and transmitting test current Iₜₑₛₜ to power switch 101, controller 170 receives output voltages V_{comp} and Vₚₑₐₖ which correspond to electrical characteristics of power switch 101 while power switch 101 is conducting test current Iₜₑₛₜ. As on-resistance increases over time, the magnitude of voltage Vₚₑₐₖ decreases, and the duration of the high output of voltage V_{comp} decreases. Controller 170 therefore may use one or more of voltages Vₚₑₐₖ and V_{comp} to determine an on-resistance degradation value.

The third prognostic test controller 170 may perform is the gate threshold voltage test. When gate source voltage increases from zero, the threshold voltage is the voltage at which the drain current starts increasing from zero. Below the gate threshold voltage, power switch 101 acts as a very high resistance device and device under test I_{DUT} current is near zero. Around the gate voltage threshold, power device 101 acts as a linear resistive device. Above the gate threshold voltage, power switch 101 acts as a low resistance device. A degradation in gate threshold voltage means that the gate threshold voltage has either increased or decreased from an initial gate threshold voltage. An increase in gate threshold voltage causes a lengthening in switching time, resulting in high power losses.

For most power switches, the switching times are between a few microseconds and tens of nanoseconds. Detecting drain current changing from zero within this time would require a high cost, high speed detection circuit. Instead, controller 170 opens semiconductor switch 143 of controlled resistance circuit 140 during the test, inserting the resistance of resistor 141 into the gate loop, effective to increase the switching time during the prognostic test. This slows the drain current change from zero, requiring a less expensive measurement circuit. It is important to note that due to the low energy of test current Iₜₑₛₜ, the slowed switching of power switch 101 does not affect the health of power switch 101. As the gate threshold voltage degrades, the time difference between applying a gate voltage and receiving a high output in V_{comp} from comparator 152 increases.

The fourth prognostic test controller 170 may perform is the drain current saturation test. Drain saturation current is the maximum current conducted by power switch 101 that can flow for a given gate-source voltage. When power switch 101 is fully on, i.e. the power switch receives a gate voltage above the gate threshold voltage such that the power switch acts as a low resistance device, power switch 101 can allow a maximum steady state current. As the drain current saturation is reduced, the power switch will have higher on-state losses, increased heat dissipation, and reduced maximum steady state current. To test the drain current saturation, a peak current is conducted by power switch 101 until the drain current saturation reaches a maximum value, or saturates.

To reduce the duration of peak current required to test the drain current saturation, system 100 applies a reduced gate voltage to the gate of power switch 101. The controller adjusts the gate voltage by operating semiconductor switch 137, changing the resistance observable at feedback terminal 122 of DC/DC converter 121. During normal operation, semiconductor switch 137 is off and a first voltage is transmitted to gate driver 123. When controller 170 turns on semiconductor switch 137, DC/DC converter 121 transmits a reduced voltage to gate driver 123. The reduced voltage may be configured to be above, but near, the gate threshold voltage of power switch 101. For example, the reduced voltage may be within 5% of the gate threshold voltage, while the nominal voltage may be more than 50% above the gate threshold voltage. While power switch 101 receives the reduced gate voltage and test current Iₜₑₛₜ, controller 170 receives output voltage Vₛₑₙₛₑ. As drain current saturation degrades, Vₛₑₙₛₑ decreases.

The fifth prognostic test controller 170 may perform is a short-circuit response test. Controller 170 uses test current injection circuit 110 to inject a test current into current sensor 103 having a magnitude greater than a short-circuit threshold. Controller 170 determines a short-circuit response degradation based on whether the controller 170 outputted an open signal to gate driver 123 in response to receiving voltage Vₛₑₙₛₑ corresponding to the high magnitude test current.

In certain embodiments, controller 170 receives a temperature measurement T₁₀₁ corresponding to a temperature of power switch 101 during each prognostic test. Due to differences in operating conditions, such as recent current conduction and ambient temperature, the measured temperature T₁₀₁ may vary. However, controller 170 may use the relationship between the temperature measurements T₁₀₁ taken during a specific prognostic test and the degradation value of the specific test to determine a degradation value for power switch 101.

In certain embodiments, the circuits of system 100 may be comprised of discrete components, multiple Integrated Circuits (ICs), or a single Integrated Circuit (IC). In certain embodiments, a portion of system 100 may be incorporated into a removable diagnostic test device, such as a handheld meter, a daughter board or a plug-in printed circuit board card, to name but one example. In certain embodiments, the diagnostic test device includes test current injection circuit 110, prognostic circuit 130, controlled resistance circuit 140, the plurality of measuring circuits 150, and controller 170. In certain embodiments, the diagnostic test device includes test current injection circuit 110 and controller 170.

It shall be appreciated that any or all of the foregoing features of system 100 may also be present in the other power switch systems disclosed herein, such as in power switch system 900 in FIG. 9 and power switch system 1000 in FIG. 10.

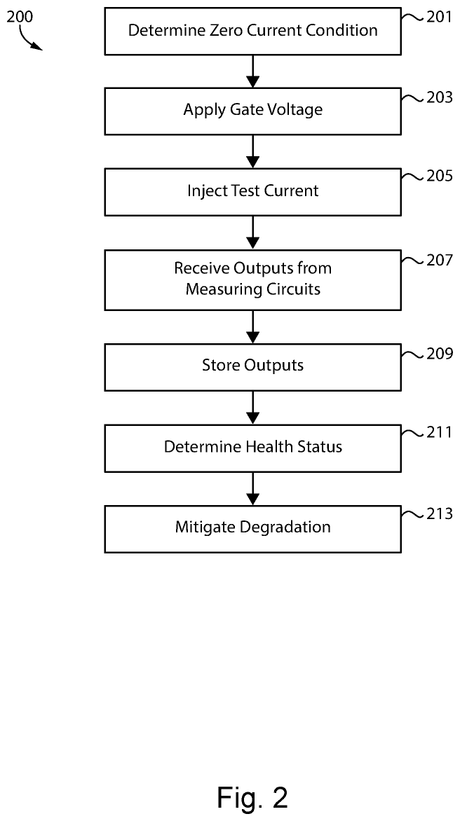

With reference to FIG. 2, there is illustrated an exemplary process for health monitoring of an exemplary power switch system, such as system 100 in FIG. 1. Process 200 may be implemented in whole or in part in one or more of the controllers disclosed herein. In certain forms, the data storage functionalities may be performed by remote systems. In certain forms, the data storage functionalities may be performed by the same controller. It shall be further appreciated that a number of variations and modifications to process 200 are contemplated including, for example, the omission of one or more aspects of process 200, the addition of further conditionals and operations, and/or the reorganization or separation of operations and conditionals into separate processes.

Process 200 begins at operation 201 where the controller determines a zero current condition is occurring. The controller may either wait for the zero current condition or open the power switch to cause the zero current condition to occur. In certain embodiments, a zero current condition occurs when the magnitude of load current is less than 1% of the peak Iₚₑₐₖ of nominal load current. In certain embodiments, a zero current condition occurs when the current conducted by the power switch is only a leakage current.

Process 200 proceeds to operation 203 where a prognostic test begins by applying a gate voltage to the power switch. Depending on the prognostic test to be performed, the controller may operate the power switch system to output a standard gate voltage to the gate of the power switch, or the controller may operate a controlled voltage circuit or a controlled resistance circuit to output a modified gate voltage to the power switch. For the on-resistance test, a standard gate voltage is applied to the power switch. For the gate threshold voltage test, the controller turns off the semiconductor switch of the controlled resistance circuit, thereby inserting a resistance into the gate loop. For the drain current saturation test, the controller turns on the semiconductor switch of the controlled voltage circuit, causing the power switch to receive a test gate voltage having a magnitude less than the standard gate voltage.

Process 200 proceeds to operation 205. While performing operation 203, process 200 executes operation 205, where the test current injection circuit transmits a test current to the current sensor coupled in series with the power switch.

Process 200 proceeds to operation 207 where the controller receives voltage outputs from the measuring circuits corresponding to electrical characteristics of the power switch while executing operations 203 and 205. In certain embodiments, the controller also receives a temperature measurement corresponding to a temperature of the power switch. Process 200 proceeds to operation 209 where the outputs are stored in memory.

Process 200 proceeds to operation 211 where the controller determines the health status of the power switch. The health status, also known as a power switch degradation value, is based on a degradation value for one or more parameters. The parameters may include gate current leakage, gate threshold voltage, on-resistance, and drain current saturation. The degradation value of each parameter may be a difference between the most recent value and a historical value of at least one of the output voltages received from the plurality of measuring circuits. The historical value is a previous value stored in memory, and may be the first value of the output voltage received from the plurality of measuring circuits. In certain embodiments, the degradation value of each parameter is a difference of a per unit value of the most recent value and a per unit value of a historical value of at least one of the output voltages received from the plurality of measuring circuits. The per unit value may be the actual value divided by a base value, the base value being a nominal value, such as the initial value of the output voltage. In certain embodiments, the degradation value of each parameter is the percentage change of the parameter.

In certain embodiments, the controller may determine the health status of the power switch using a cost function equation. For example, the controller may use the following equation, where D_{PS} is the degradation value for the power switch, D_{GL} is the degradation value for the gate leakage current parameter, D_{GV} is the degradation value for the gate threshold voltage parameter, D_{OR} is the degradation value for the on-resistance parameter, D_{DS} is the degradation value for the drain current saturation parameter, and k₁-k₄ are weighting factors for each parameter degradation value.

D_{PS}=k₁*D_{GL}+k₂*D_{GV}+k₃*D_{OR}+k₄*D_{DS} (1)

Each of the parameter degradation values may be determined by the following equation set, where V_{gate_present} is a value of V_{gate} received by the controller during the most recent gate leakage current test, V_{gate_historical} is a value of V_{gate} received by the controller during a historical gate leakage current test, T_{V}_{_{comp}}_{_delay_present} is a value of the time delay of the high output in V_{comp} during the most recent gate threshold voltage test, T_{V}_{_{comp}}_{_delay_historical} is a value of the time delay of the high output in V_{comp} during a historical gate threshold voltage test, V_{peak_present} is a value of Vₚₑₐₖ received by the controller during the most recent on-resistance test, V_{peak_historical} is a value of Vₚₑₐₖ received by the controller during a historical on-resistance test. Vₛₑₙₛₑ present is a value of Vₛₑₙₛₑ received by the controller during the most recent drain current saturation test, and V_{sense_historical} is a value of Vₛₑₙₛₑ received by the controller during a historical drain current saturation test:

$${D}_{GL} = \frac{{V}_{gate\_present} - {V}_{gate\_historical}}{{V}_{gate\_historical}} \\ {D}_{GV} = \vert \frac{{T}_{{V}_{comp} - delay\_present} - {T}_{{V}_{comp} - delay\_historical}}{{T}_{{V}_{comp} - delay\_historical}} \vert \\ {D}_{OR} = \vert \frac{{V}_{peak\_present} - {V}_{peak\_historical}}{{V}_{peak\_historical}} \vert \\ {D}_{DS} = \vert \frac{{V}_{sense\_present} - {V}_{sense\_historical}}{{V}_{sense\_historical}} \vert \qquad ( 2 )$$

In certain embodiments, the degradation value for the on-resistance parameter may be determined using the following equation, where T_{V}_{_{comp}}_{_period_present} is a value of the time period of the high output in V_{comp} during the most recent on-resistance test, and T_{V}_{_{comp}}_{_period_historical} is a value of the time period of the high output in V_{comp} during the most recent on-resistance test:

$${D}_{GV} = \vert \frac{{T}_{{V}_{comp} - period\_present} - {T}_{{V}_{comp} - period\_historical}}{{T}_{{V}_{comp} - period\_historical}} \vert \qquad ( 3 )$$

In certain embodiments, determining the health status of the power switch includes comparing received and stored values of temperature measurements, or comparing the relationship between the values of temperature measurements taken during a specific prognostic test and the determined degradation values of the prognostic test.

Process 200 proceeds to operation 213 where the controller mitigates the power switch degradation. The controller may mitigate the degradation by transmitting a warning to an end user or disabling the power switch. In certain embodiments, the controller may transmit a warning to an end user if the power switch degradation value exceeds a first threshold, and may disable the power switch if the power switch degradation value exceeds a second threshold.

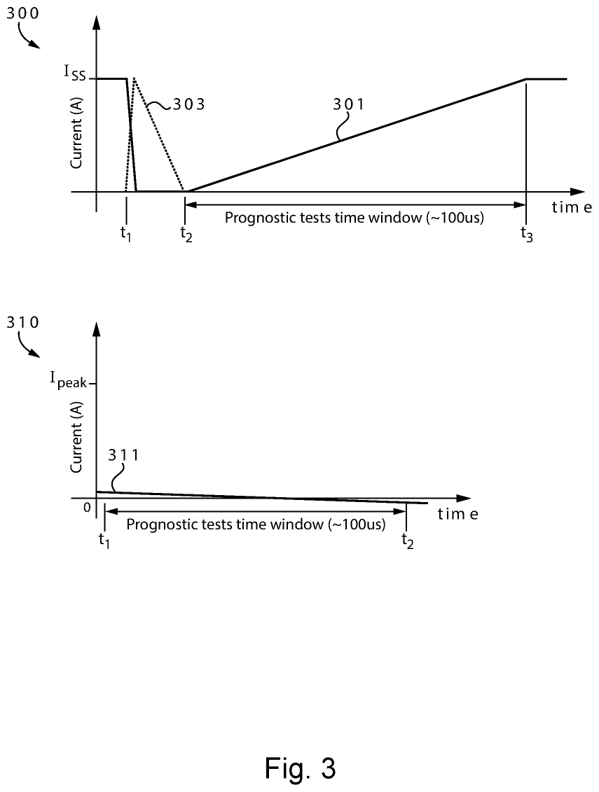

With reference to FIG. 3 there is a plurality of graphs illustrating exemplary zero current conditions. Graph 300 illustrates a zero current condition generated by opening an exemplary power switch and waiting until MOV transients terminate. Graph 300 includes a load current 301 and an MOV current 303. At time instant t₁, the controller turns off the power switch causing load current 301 to decrease sharply and MOV current 303 to increase sharply. At time instant t₂, MOV current 303 has decreased to zero, causing a zero current condition where the controller may begin prognostic testing by turning on the power switch. Between turning on the power switch and time instant t₃, load current 301 increases during a prognostic test time window. At time instant t₃, load current 301 returns to steady state magnitude I_{SS}.

Graph 310 illustrates a zero current condition at a load current zero crossing. Graph 310 includes a load current 311 having a magnitude less than a peak of nominal load current Iₚₑₐₖ. In certain embodiments, a zero current condition occurs at a load current zero crossing when the magnitude of load current 311 is less than 1% of the peak Iₚₑₐₖ of nominal load current.

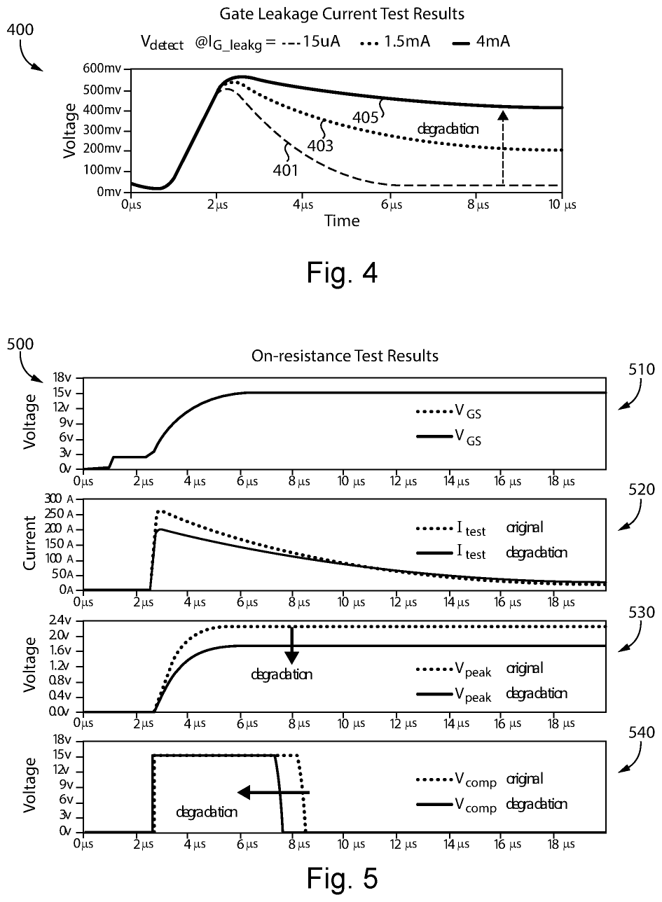

With reference to FIG. 4, there is a graph 400 illustrating exemplary gate leakage current test results over the life of power switch. Graph 400 includes a first line 401 representing voltage V_{gate} of an initial gate leakage current of 15 uA for the power switch, a second line 403 representing voltage V_{gate} of an intermediate gate leakage current of 1.5 mA for the power switch, and a third line 405 representing voltage V_{gate} of the most recent gate leakage current of 4 mA for the power switch. As illustrated in graph 400, once the power switch reaches steady state, at approximately 6 us, it is clear from voltage V_{gate} that leakage current through power switch 101 is increasing, degradation the power switch.

With reference to FIG. 5, there is a plurality of graphs 500 illustrating exemplary on-resistance test results for an exemplary power switch in original condition and in a degraded condition. Graph 510 illustrates the gate-source voltage of the power switch during the test. Graph 520 illustrates the magnitudes of tests currents Iₜₑₛₜ. Graph 530 illustrates voltages Vₚₑₐₖ. Graph 540 illustrates voltage V_{comp}. As illustrated in graph 520, the peak of the test current is reduced as on-resistance degrades, which is reflected in the reduction of the magnitude of voltage Vₚₑₐₖ in graph 530. Furthermore, the reduction of test current magnitude causes the time period of the high output in voltage V_{comp}, illustrated in graph 540, to decrease.

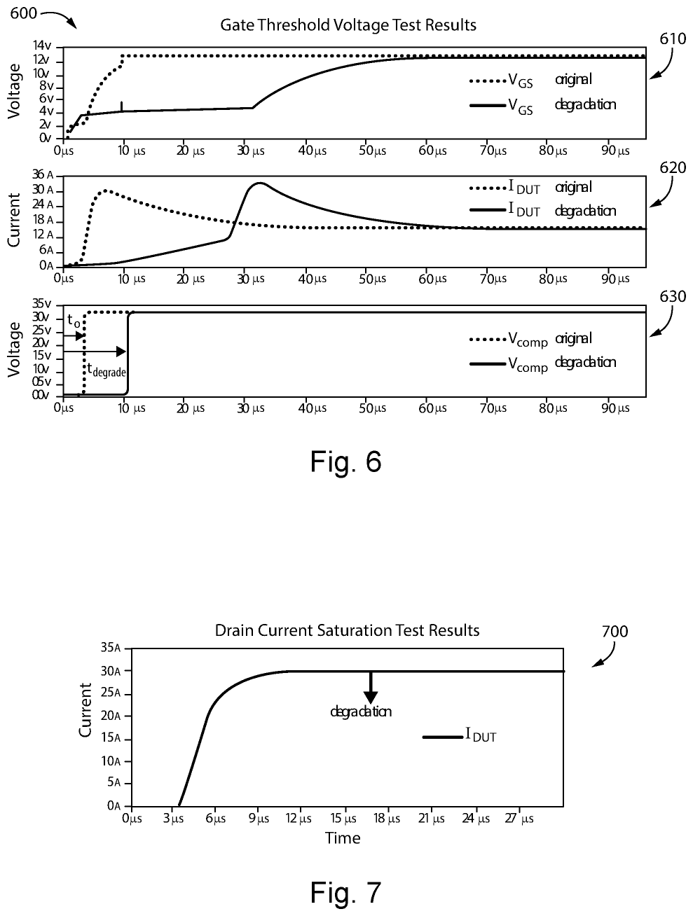

With reference to FIG. 6, there is a plurality of graphs 600 illustrating exemplary gate threshold voltage test results for an exemplary power switch in an original condition and in a degraded condition. Graph 610 illustrates the gate-source voltages V_{GS}. Graph 620 illustrates magnitudes of device under test current I_{DUT}, which includes test current Iₜₑₛₜ. Graph 630 illustrates the voltages V_{comp}. In the degraded condition, the power switch reaches the gate threshold voltage more slowly, as shown by the delayed current magnitude increase in graph 620 and the corresponding delay in high output in voltage V_{comp}.

With reference to FIG. 7, there is a graph 700 illustrating exemplary drain current saturation test results for an exemplary power switch. Graph 700 includes a device under test current I_{DUT}, which includes test current Iₜₑₛₜ. In a degraded condition, the magnitude of current I_{DUT} decreases.

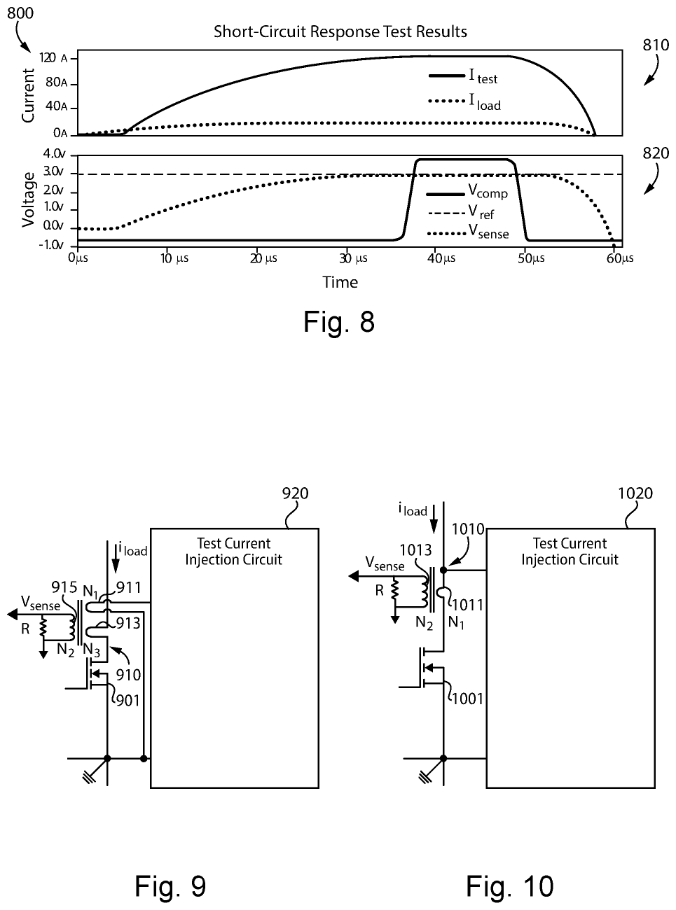

With reference to FIG. 8, there are graphs illustrating exemplary short-circuit response results for an exemplary power switch. Graph 810 illustrates a test current Iₜₑₛₜ and a load current I_{load} conducted through the current sensor. Graph 820 illustrates voltage Vₛₑₙₛₑ output by the current sensor, voltage V_{comp} output by the threshold measuring circuit, and a short-circuit threshold voltage V_{ref}. Once voltage Vₛₑₙₛₑ, which corresponds to the magnitude of the combination of current I_{load} and test current Iₜₑₛₜ, exceeds voltage V_{ref}, voltage V_{comp} increases to a high output until power switch opens in response to the controller transmitting an open signal the gate driver.

With reference to FIG. 9, there is illustrated an exemplary power switch system 900 including a power switch 901. System 900 includes a current transformer 910 including a first winding 911 coupled in parallel with a test current injection circuit 920, a second winding coupled in series with power switch 901, and a third winding 915 structured to output voltage Vₛₑₙₛₑ.

With reference to FIG. 10, there is illustrated an exemplary power switch system 1000 including a power switch 1001. System 1000 includes a current transformer 1010 including a first winding 1011 coupled in series with power switch 1001 such that test current injection circuit 1020 is coupled in parallel with the series coupled power switch 1001 and winding 1011, and a second winding 1013 structured to output voltage Vₛₑₙₛₑ.

From the foregoing, it shall be appreciated that one example embodiment is a power switch system comprising: a power switch; a current sensor coupled in series with the power switch; a test current injection circuit comprising: a first direct current (DC) bus rail including an output terminal and a first power supply terminal, a second DC bus rail including an input terminal and a second power supply terminal, a diode coupled to the first DC bus rail, and a leg coupled to the first DC bus rail between the diode and the first power supply terminal and coupled to the second DC bus rail between the input terminal and the second power supply terminal, the leg including a capacitor and a semiconductor device coupled in series; and a controller configured to operate the test current injection circuit to transmit a test current to the current sensor and receive an output voltage based on the test current. In certain forms, the controller determines a health status of the power switch based on a gate leakage current degradation value, an on-resistance degradation value, a gate threshold voltage degradation value, and a drain current saturation degradation value. Certain forms comprise an amplifier, and wherein the controller is configured to receive the output voltage from the amplifier and determine the gate leakage current degradation value based on the output voltage and a historical output voltage received from the amplifier. Certain forms, comprise a controlled voltage circuit including a first resistor coupled in parallel with a second resistor and a switching device, wherein the controlled voltage circuit is structured to output a first gate voltage when the switching device is in a first state and a test gate voltage when the switching device is in a second state, the test gate voltage being less than the first gate voltage, wherein the controller is configured to operate the test current injection circuit to transmit the test current to the current sensor while the controlled voltage circuit is outputting the test gate voltage, receive the output voltage from the current sensor, and determine the drain current saturation degradation value based on the output voltage and a historical output voltage received from the current sensor. Certain forms comprise a comparator, wherein the comparator is configured to receive the output voltage from the current sensor, compare the output voltage to a reference voltage corresponding to a gate threshold voltage of the power switch, and transmit a high output to the controller while the output voltage exceeds the reference voltage. Certain forms comprise a gate driver; a resistor coupled between the gate driver and a gate of the power switch; and a switching device coupled in parallel with the resistor, wherein the controller is configured to open the switching device while the controller is operating the test current injection circuit to transmit the test current to the current sensor, determine a time delay between transmitting the test current and receiving the high output from the comparator, and determine the gate threshold voltage degradation value based on the time delay and a historical time delay. Certain forms comprise a peak measurement circuit structured to receive the output voltage and output a peak voltage corresponding to a peak current magnitude of the test current, and wherein the controller is configured to determine the on-resistance degradation value based on at least one of the peak voltage and a duration of the high output. In certain forms, the test current includes a magnitude greater than a short-circuit threshold, and wherein the controller determines a health status of the controller in response to determining whether the controller outputted an open signal to a gate driver in response to the test current injection circuit transmitting the test current. In certain forms, the test current injection circuit comprises a resistor coupled to the first DC bus between the diode and the leg, wherein the diode is structured to block a load current from conducting through the leg, and wherein the semiconductor device includes a semiconductor switch and a second diode, the semiconductor device being arranged to conduct a charging current flowing between the first power supply terminal and the second power supply terminal. In certain forms, the controller operates the test current injection circuit to transmit the test current to the current sensor after determining the power switch is in a zero current condition.

Another example embodiment is a method comprising: operating a power switch system including: a power switch, a current sensor coupled in series with the power switch, and a test current injection circuit including: a first direct current (DC) bus rail including an output terminal and a first power supply terminal, a second DC bus rail including an input terminal and a second power supply terminal, a diode coupled to the first DC bus rail, and a leg coupled to the first DC bus rail between the diode and the first power supply terminal and coupled to the second DC bus rail between the input terminal and the second power supply terminal, the leg including a capacitor and a semiconductor device coupled in series; transmitting, with the test current injection circuit, a test current to the current sensor; and receiving an output voltage based on the test current. Certain forms comprise determining a health status of the power switch based on a gate leakage current degradation value, an on-resistance degradation value, a gate threshold voltage degradation value, and a drain current saturation degradation value. In certain forms, receiving the output voltage includes receive the output voltage from an amplifier, and wherein the method comprises determining the gate leakage current degradation value based on the output voltage and a historical output voltage received from the amplifier. Certain forms comprise operating a controlled voltage circuit including DC/DC converter, a switching device configured to control an output of the DC/DC converter, and a gate driver to output a first gate voltage based on a first state of the switching device and a test gate voltage based on a second state of the switching device, the test gate voltage being less than a first gate voltage; outputting the first gate voltage while operating the test current injection circuit to transmit the test current to the current sensor; receiving the output voltage from the current sensor; and determining the drain current saturation degradation value based on the output voltage and a historical output voltage received from the current sensor. In certain forms, receiving the output voltage includes receiving, with a comparator, the output voltage from the current sensor, and wherein the method comprises: comparing the output voltage to a reference voltage, and transmitting, with the comparator, a high output while the output voltage exceeds the reference voltage. Certain forms comprise operating a gate driver and a controlled resistance circuit including: a resistor coupled between the gate driver and a gate of the power switch, and a switching device coupled in parallel with the resistor, opening the switching device while the controller is operating the test current injection circuit to transmit the test current to the current sensor; determining a time delay between beginning to transmit the test current and receiving the high output from the comparator; and determining the gate threshold voltage degradation value based on the time delay and a historical time delay. Certain forms comprise outputting a peak voltage, with a peak measurement circuit, based on the output voltage, the peak voltage corresponding to a peak current magnitude of the test current; and determining the on-resistance degradation value based on at least one of the peak voltage and a duration of the high output. In certain forms, the test current is configured to cause an output voltage having a magnitude greater than a short-circuit threshold, and wherein the method comprises determining a health status of a controller including determining whether the controller outputted an open signal to a gate driver in response to the test current injection circuit transmitting the test current. In certain forms, the test current injection circuit includes a resistor coupled to the first DC bus between the diode and the leg, wherein the diode is structured to block a load current from conducting through the leg, and wherein the semiconductor device includes a second diode arranged to conduct a charging current flowing between the first power supply terminal and the second power supply terminal. In certain forms, operating the test current injection circuit to transmit the test current to the current sensor occurs after determining the power switch is in a zero current condition.

A further example embodiment is an apparatus for testing a power switch system, the apparatus comprising: a test current injection device including: a first direct current (DC) bus rail including an output terminal and a first power supply terminal; a second DC bus rail including an input terminal and a second power supply terminal; a diode coupled to the first DC bus rail; and a leg coupled to the first DC bus rail between the diode and the first power supply terminal and coupled to the second DC bus rail between the input terminal and the second power supply terminal, the leg including a capacitor and a semiconductor device coupled in series; wherein the test current injection device is structured to transmit a test current by way of the output terminal. In certain forms, the test current injection device is structured to be coupled to a power system including a current sensor coupled in series with a power switch. In certain forms, the apparatus receives an output voltage from the current sensor based on the test current. In certain forms, the test current injection device comprises a resistor coupled to the first DC bus between the diode and the leg, wherein the diode is structured to block a load current from conducting through the leg, and wherein the semiconductor device includes a second diode arranged to conduct a charging current flowing between the first power supply terminal and the second power supply terminal.

It is contemplated that the various aspects, features, processes, and operations from the various embodiments may be used in any of the other embodiments unless expressly stated to the contrary. Certain operations illustrated may be implemented by a computer including a processing device executing a computer program product on a non-transient, computer-readable storage medium, where the computer program product includes instructions causing the processing device to execute one or more of the operations, or to issue commands to other devices to execute one or more operations.

While the present disclosure has been illustrated and described in detail in the drawings and foregoing description, the same is to be considered as illustrative and not restrictive in character, it being understood that only certain exemplary embodiments have been shown and described, and that all changes and modifications that come within the spirit of the present disclosure are desired to be protected. It should be understood that while the use of words such as “preferable,” “preferably,” “preferred” or “more preferred” utilized in the description above indicate that the feature so described may be more desirable, it nonetheless may not be necessary, and embodiments lacking the same may be contemplated as within the scope of the present disclosure, the scope being defined by the claims that follow. In reading the claims, it is intended that when words such as “a,” “an,” “at least one,” or “at least one portion” are used there is no intention to limit the claim to only one item unless specifically stated to the contrary in the claim. The term “of” may connote an association with, or a connection to, another item, as well as a belonging to, or a connection with, the other item as informed by the context in which it is used. The terms “coupled to,” “coupled with” and the like include indirect connection and coupling, and further include but do not require a direct coupling or connection unless expressly indicated to the contrary. When the language “at least a portion” and/or “a portion” is used, the item can include a portion and/or the entire item unless specifically stated to the contrary.

1. A power switch system comprising:
a power switch;
a current sensor coupled in series with the power switch;
a test current injection circuit comprising:
a first direct current (DC) bus rail including an output terminal and a first power supply terminal,
a second DC bus rail including an input terminal and a second power supply terminal,
a diode coupled to the first DC bus rail, and
a leg coupled to the first DC bus rail between the diode and the first power supply terminal and coupled to the second DC bus rail between the input terminal and the second power supply terminal, the leg including a capacitor and a semiconductor device coupled in series; and
a controller configured to operate the test current injection circuit to transmit a test current to the current sensor and receive an output voltage based on the test current.

2. The power switch system of claim 1, wherein the controller determines a health status of the power switch based on a gate leakage current degradation value, an on-resistance degradation value, a gate threshold voltage degradation value, and a drain current saturation degradation value.

3. The power switch system of claim 2, comprising an amplifier, and wherein the controller is configured to receive the output voltage from the amplifier and determine the gate leakage current degradation value based on the output voltage and a historical output voltage received from the amplifier.

4. The power switch system of claim 2, comprising a controlled voltage circuit including a first resistor coupled in parallel with a second resistor and a switching device, wherein the controlled voltage circuit is structured to output a first gate voltage when the switching device is in a first state and a test gate voltage when the switching device is in a second state, the test gate voltage being less than the first gate voltage, wherein the controller is configured to operate the test current injection circuit to transmit the test current to the current sensor while the controlled voltage circuit is outputting the test gate voltage, receive the output voltage from the current sensor, and determine the drain current saturation degradation value based on the output voltage and a historical output voltage received from the current sensor.

5. The power switch system of claim 2, comprising a comparator, wherein the comparator is configured to receive the output voltage from the current sensor, compare the output voltage to a reference voltage corresponding to a gate threshold voltage of the power switch, and transmit a high output to the controller while the output voltage exceeds the reference voltage.

6. The power switch system of claim 5, comprising:
a gate driver;
a resistor coupled between the gate driver and a gate of the power switch; and
a switching device coupled in parallel with the resistor,
wherein the controller is configured to open the switching device while the controller is operating the test current injection circuit to transmit the test current to the current sensor, determine a time delay between transmitting the test current and receiving the high output from the comparator, and determine the gate threshold voltage degradation value based on the time delay and a historical time delay.

7. The power switch system of claim 5, comprising a peak measurement circuit structured to receive the output voltage and output a peak voltage corresponding to a peak current magnitude of the test current, and wherein the controller is configured to determine the on-resistance degradation value based on at least one of the peak voltage and a duration of the high output.

8. The power switch system of claim 1, wherein the test current includes a magnitude greater than a short-circuit threshold, and wherein the controller determines a health status of the controller in response to determining whether the controller outputted an open signal to a gate driver in response to the test current injection circuit transmitting the test current.

9. The power switch system of claim 1, wherein the test current injection circuit comprises a resistor coupled to the first DC bus between the diode and the leg, wherein the diode is structured to block a load current from conducting through the leg, and wherein the semiconductor device includes a semiconductor switch and a second diode, the semiconductor device being arranged to conduct a charging current flowing between the first power supply terminal and the second power supply terminal.

10. The power switch system of claim 1, wherein the controller operates the test current injection circuit to transmit the test current to the current sensor after determining the power switch is in a zero current condition.

11. A method comprising:
operating a power switch system including:
a power switch,
a current sensor coupled in series with the power switch, and
a test current injection circuit including:
a first direct current (DC) bus rail including an output terminal and a first power supply terminal,
a second DC bus rail including an input terminal and a second power supply terminal,
a diode coupled to the first DC bus rail, and
a leg coupled to the first DC bus rail between the diode and the first power supply terminal and coupled to the second DC bus rail between the input terminal and the second power supply terminal, the leg including a capacitor and a semiconductor device coupled in series;
transmitting, with the test current injection circuit, a test current to the current sensor; and
receiving an output voltage based on the test current.

12. The method of claim 11, comprising determining a health status of the power switch based on a gate leakage current degradation value, an on-resistance degradation value, a gate threshold voltage degradation value, and a drain current saturation degradation value.

13. The method of claim 12, wherein receiving the output voltage includes receive the output voltage from an amplifier, and wherein the method comprises determining the gate leakage current degradation value based on the output voltage and a historical output voltage received from the amplifier.

14. The method of claim 12, comprising:
operating a controlled voltage circuit including DC/DC converter, a switching device configured to control an output of the DC/DC converter, and a gate driver to output a first gate voltage based on a first state of the switching device and a test gate voltage based on a second state of the switching device, the test gate voltage being less than a first gate voltage;
outputting the first gate voltage while operating the test current injection circuit to transmit the test current to the current sensor;
receiving the output voltage from the current sensor; and
determining the drain current saturation degradation value based on the output voltage and a historical output voltage received from the current sensor.

15. The method of claim 12, wherein receiving the output voltage includes receiving, with a comparator, the output voltage from the current sensor, and wherein the method comprises:
comparing the output voltage to a reference voltage, and
transmitting, with the comparator, a high output while the output voltage exceeds the reference voltage.

16. The method of claim 15, comprising:
operating a gate driver and a controlled resistance circuit including:
a resistor coupled between the gate driver and a gate of the power switch, and
a switching device coupled in parallel with the resistor,
opening the switching device while the controller is operating the test current injection circuit to transmit the test current to the current sensor;
determining a time delay between beginning to transmit the test current and receiving the high output from the comparator; and
determining the gate threshold voltage degradation value based on the time delay and a historical time delay.

17. The method of claim 15, comprising:
outputting a peak voltage, with a peak measurement circuit, based on the output voltage, the peak voltage corresponding to a peak current magnitude of the test current; and
determining the on-resistance degradation value based on at least one of the peak voltage and a duration of the high output.

18. The method of claim 11, wherein the test current is configured to cause an output voltage having a magnitude greater than a short-circuit threshold, and wherein the method comprises determining a health status of a controller including determining whether the controller outputted an open signal to a gate driver in response to the test current injection circuit transmitting the test current.

19. The method of claim 11, wherein the test current injection circuit includes a resistor coupled to the first DC bus between the diode and the leg, wherein the diode is structured to block a load current from conducting through the leg, and wherein the semiconductor device includes a second diode arranged to conduct a charging current flowing between the first power supply terminal and the second power supply terminal.

20. The method of claim 11, wherein operating the test current injection circuit to transmit the test current to the current sensor occurs after determining the power switch is in a zero current condition.

21. An apparatus for testing a power switch system, the apparatus comprising:
a test current injection device including:
a first direct current (DC) bus rail including an output terminal and a first power supply terminal;
a second DC bus rail including an input terminal and a second power supply terminal;
a diode coupled to the first DC bus rail; and
a leg coupled to the first DC bus rail between the diode and the first power supply terminal and coupled to the second DC bus rail between the input terminal and the second power supply terminal, the leg including a capacitor and a semiconductor device coupled in series;
wherein the test current injection device is structured to transmit a test current by way of the output terminal.

22. The apparatus of claim 21, wherein the test current injection device is structured to be coupled to a power system including a current sensor coupled in series with a power switch.

23. The apparatus of claim 22 wherein the apparatus receives an output voltage from the current sensor based on the test current.

24. The apparatus of claim 21, wherein the test current injection device comprises a resistor coupled to the first DC bus between the diode and the leg, wherein the diode is structured to block a load current from conducting through the leg, and wherein the semiconductor device includes a second diode arranged to conduct a charging current flowing between the first power supply terminal and the second power supply terminal.
